(19) United States
(12) Patent Application Publication
(10) Pub. No.: US 2026/0031127 A1
(43) Pub. Date: Jan. 29, 2026

(54) APPARATUSES SYSTEMS AND METHODS FOR PRAC GAP COUNTING

(71) Applicant: Micron Technology, Inc., Boise, ID (US)

(72) Inventor: Masaru Nara, Kanagawa (JP)

(73) Assignee: Micron Technology, Inc., Boise, ID (US)

(21) Appl. No.: 19/268,763

(22) Filed: Jul. 14, 2025

Related U.S. Application Data
(60) Provisional application No. 63/676,507, filed on Jul. 29, 2024.

(51) Int. Cl. G11C 11/406

(52) U.S. Cl. CPC G11C 11/406

(57) ABSTRACT

A memory device performs a set of targeted refresh operations based on an aggressor address. The last targeted refresh operation in the set is a reset targeted refresh operation. The memory device sets a per-row access count (PRAC) value based on the number of access operations which have occurred in the gap between the first targeted refresh operation in the set and the reset targeted refresh operation. For example, when the first targeted refresh operation is performed on an address, the PRAC value is locked in an aggressor register. As part of the reset targeted refresh operation, the current PRAC value is read out and compared to the stored PRAC value. The difference between those values is written as the new PRAC value.

### CROSS REFERENCE TO RELATED APPLICATION(S)

This application claims the benefit under 35 U.S.C. § 119 of the earlier filing date of U.S. Provisional Application Ser. No. 63/676,507 filed Jul. 29, 2024 the entire contents of which is hereby incorporated by reference in its entirety for any purpose.

### BACKGROUND

This disclosure relates generally to semiconductor devices, and more specifically to semiconductor memory devices. In particular, the disclosure relates to volatile memory, such as dynamic random access memory (DRAM). Information is stored in the memory on memory cells as a physical signal such as a charge on a capacitive element. During an access operation, an access command may be received along with address information which specifies which memory cells should be accessed.

Information may decay over time in the memory cells. For example, the memory cells may discharge over time. In order to preserve the integrity of the stored information, the memory cells may be refreshed, for example to restore an initial charge level associated with the stored information. Various refresh operations, such as normal and targeted refresh operations may be performed. Targeted refresh operations may generally be performed in a set, based on an identified aggressor word line. The aggressor word line may be identified, at least in part, based on a count of accesses to the word line. However, certain patterns of operation may cause accesses to the word line in between the set of targeted refresh operations based on that word line. There may be a need to account for these access operations.

### BRIEF DESCRIPTION OF THE DRAWINGS

FIG. 1 is a block diagram of a semiconductor device according to some embodiments of the disclosure.

FIG. 2 is a block diagram of bank logic according to some embodiments of the present disclosure.

FIG. 3 is a block diagram of gap logic circuits according to some embodiments of the present disclosure.

FIG. 4 is a chart of an example sequence of operations according to some embodiments of the present disclosure.

FIG. 5 is a flow chart of a method of adjusting PRAC values based on activations during a targeted refresh gap according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells. The memory cells are at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

Information in the memory cells may decay over time. For example, the memory cells may include capacitive elements which store information based on the level of charge in the capacitive element. The charge may ‘leak’ over time, which may degrade the information stored therein. The memory performs refresh operation to restore the information in the memory cells. For example, the amount of charge may be restored to an initial level. The memory may perform refresh operations by counting through the row addresses of the bank. The rate at which refresh operations may be based on an expected rate at which the information decays.

Certain operation patterns may increase the rate at which the information decays. For example, repeated activations of a word line, known as a row hammer, may increase the rate of information decay along nearby word lines. The memory may count accesses to the word lines, for example using per-row access counts (PRAC). Based on those counts, the memory device may identify word lines as aggressor word lines and then perform targeted refresh operations on the nearby or victim word lines. Targeted refresh operations may generally come in sets of operations. For example, the memory device may perform a first targeted refresh operation on a first victim word line (e.g., the adjacent word line on one side of the aggressor), perform a refresh operation on a second victim word line (e.g., the adjacent word line on the other side of the aggressor) and then perform a third operation to reset the PRAC on the aggressor word line.

There may be some situations where one or more row activations commands are received between targeted refresh operations of a set. In some situations, these activations may be performed on the row where the targeted refresh operations have already started being performed. Since the PRAC of this row will be reset at the end of the set of targeted refresh operations, any additional activations received during this gap, or period of time between targeted refresh operations of the set, will be lost information. However, these activations may still affect the victim word lines. There may be a need to preserve the number of these gap activations to maintain appropriate PRAC operations.

The present disclosure is drawn to apparatuses, systems, and methods for PRAC gap counting. When a word line is accessed, an access count update (ACU) logic circuit performs an ACU operation by updating the PRAC along that word line. If the PRAC crosses a threshold, the row address and PRAC count associated with that word line are added to an aggressor queue which includes a register. When a set of targeted refresh operations is performed on one of the row addresses in the queue, the current PRAC value of the aggressor word line is locked in the queue. At the end of a set of targeted refresh operations based on that aggressor address, the memory performs a reset targeted refresh operation. During the rest targeted refresh operation, the PRAC along the aggressor word line is accessed and compared to the value stored in the aggressor queue at the beginning of the set of targeted refresh operations. The difference between the current PRAC and the stored PRAC is written back to the word line as the new PRAC value. In this manner, any activations which were counted during the gap between the beginning of the set of targeted refresh operations and the reset targeted refresh operation are preserved in the new PRAC value written to the word line at the end of the set of targeted refresh operations. This may allow for more accurate counting of activations, which in turn may allow for adjustments such as an increase in the alert threshold at which an alert is sent to the controller when one or more of the PRAC counts crosses the alert threshold.

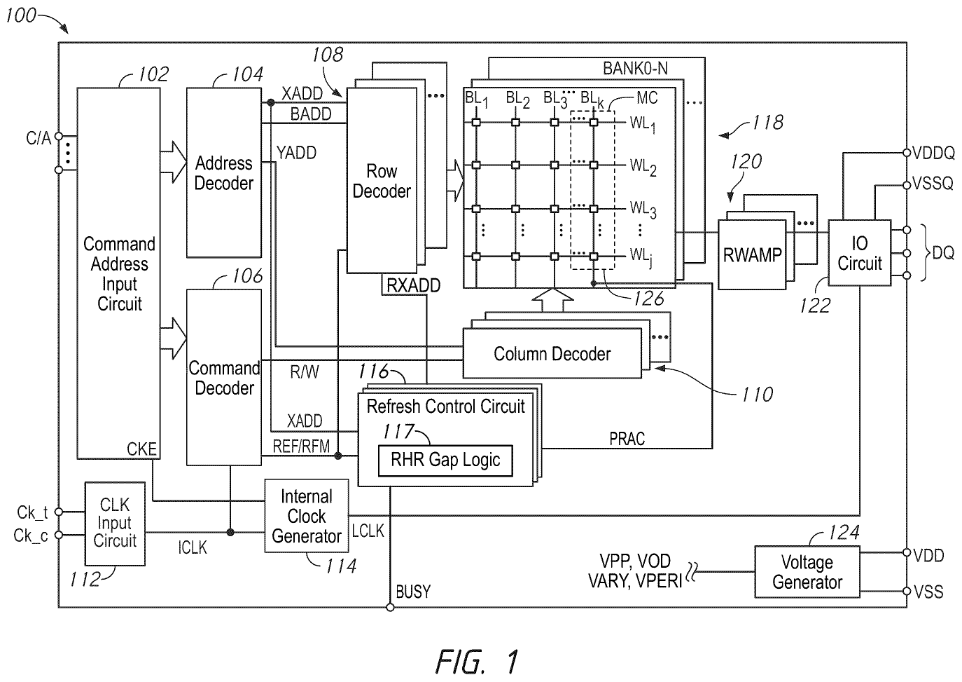

FIG. 1 is a block diagram of a semiconductor device according to some embodiments of the disclosure. The semiconductor device 100 may be a semiconductor memory device, such as a DRAM device integrated on a single semiconductor chip. In some embodiments, the semiconductor device 100 may represent one of a number of memory devices packaged together, such as on a module. In some embodiments, the semiconductor device 100 may represent a stand-alone memory device.

The semiconductor device 100 includes a memory array 118. The memory array 118 is organized into a plurality of memory banks. In the embodiment of FIG. 1, the memory array 118 is shown as including N+1 memory banks labeled BANKO to BANKN. For example, a memory array 118 may include 4, 8, 16, or any other number of memory banks. More or fewer banks may be included in the memory array 118 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP and transferred to read/write amplifier (RWAMP) circuit 120 over local data lines (LIO), transfer gate (TG), and global data lines (GIO). Conversely, write data outputted from the RWAMP circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A or CA) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ. The external terminals may also generally be referred to as ‘pins’ such as C/A pins. In some embodiments, the external terminals may couple directly to a host or controller of the memory device 100. In some embodiments, the external terminals may couple to various buses/connectors of a module or other package. The terminals may also be referred to as pins. In some embodiments, each terminal may generally receive a first voltage which represents a logical high or a second voltage which represents a logical low. Other schemes, such as multi-level signaling (e.g., PAM4) may be used in other example embodiments.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command/address input circuit 102, to an address decoder 104. The address decoder 104 decodes the address into a bank address, row address, and column address. The bank address BADD selects the row decoder 108 and column decoder 110 and thus selects the bank. The address decoder 104 supplies a decoded row address XADD to the row decoder 108 selected by BADD and supplies a decoded column address YADD to the column decoder 110 selected by BADD. The decoded row address XADD may be used to determine which row is opened or activated, coupling the memory cells along the activated word line to the intersecting bit lines. The column decoder 110 provides a column select signal CS based on the column address YADD. The CS signal selects which bit lines are coupled to local input/output lines, allowing those bit lines to be accessed.

The C/A terminals may be supplied with commands. Examples of commands include timing commands for controlling the timing of various operations, row activation commands to activate selected word lines, column commands such as read or write for accessing memory cells along an active word line, pre-charge commands for inactivating or closing an active word line, refresh commands such as all-bank refresh, same bank refresh, per-bank refresh, and refresh management commands, as well as other commands and operations. Access commands are performed by sending row activation, column command, and pre-charge commands. The access commands may be associated with one or more row address XADD, column address YADD, and bank address BADD to indicate the memory cell(s) to be accessed. In some embodiments, the command and address may be transmitted together as a command packet along the C/A terminals. For example, a row activation command may be transmitted along with row address and bank address, and a column command (e.g., a read or write) may be transmitted along with a column address. The input circuit 102 separates the command portion of the packet from the address portion and provides the command portion to the command decoder 106 and the address portion to the address decoder 104.

The commands may be provided as internal command signals to a command decoder 106 via the command/address input circuit 102. The command decoder 106 includes circuits to decode the internal command signals to generate various internal signals and commands for performing operations. For example, the command decoder 106 may provide signals to indicate if data is to be read, written, etc. Responsive to an activation command received at the C/A terminals, as part of an access operation the command decoder 106 provides an internal row activation command or internal row activation signal ACT and an internal pre-charge command or internal pre-charge signal Pre. The row decoder 108 activates a word line responsive to the internal activation signal ACT and deactivates (or pre-charges) the word line responsive to the internal pre-charge signal Pre.

The memory array 118 includes a set of counter memory cells 126 which are used to store PRAC values associated with the word lines of the array. For example, each word line may have a number of counter memory cells 126 along it which store the PRAC for that word line. Other arrangements may be used in other example embodiments. When that word line is accessed, the PRAC associated with the word line is read out to a refresh control circuit 116, which updates the PRAC and checks to see if it has crossed a threshold, and writes it back to the counter memory cells 126 as part of a read/modify/write operation. In some embodiments, the PRAC may be updated responsive to the row activation command. In some embodiments, the PRAC may be updated responsive to the pre-charge command.

In an example write operation, the device 100 writes data received at the DQ terminals to the memory cells specified by a received bank, row and column address. As part of the write operation, the command decoder 106 receives a write command and activation command and provides internal signals such as W and ACT/Pre. The write data is received by the IO circuit 122 and provided to the RWAMP circuit 120. The row decoder 108 selected by BADD activates the word line selected by XADD responsive to the internal activation signal ACT. The column decoder 110 selected by BADD couples the bit lines selected by YADD to the LIO and GIO lines to the RWAMP circuit 120. The sense amplifiers drive the voltages on the coupled bit lines to write the write data to the memory cells at the intersection with the active word line. The PRAC associated with the activated word line is read out from the counter memory cells 126 associated with the active word line, updated, and written back to those counter memory cells 126. Responsive to a pre-charge command, the row decoder 108 pre-charges the word line.

In an example read operation, the device 100 reads data from the memory cells specified by a received bank, row, and column address and provides that read data to the DQ terminals. As part of the read operation, the command decoder 106 receives a read command and an activation command and provides internal signals such as a read signal R, and ACT/Pre. The row decoder 108 selected by BADD activates the row selected by XADD responsive to the internal row activation signal ACT. The column decoder 110 selected by BADD couples the bit lines selected by YADD to the LIO and GIO lines to the RWAMP circuit 120. The RWAMP circuit 120 provides the read data to the IO circuit 122 and the IO circuit 122 provides the read data to the DQ terminals. The PRAC associated with the activated word line is read out from the counter memory cells 126 associated with the active word line, updated, and written back to those counter memory cells 126. Responsive to a pre-charge command, the row decoder 108 pre-charges the word line.

The device 100 includes refresh control circuits 116 each associated with a bank of the memory array 118. The refresh control circuit 116 performs refresh operations on the associated bank 118. The refresh control circuit 116 generates a refresh address RXADD and provides it to the row decoder 108. Responsive to a refresh signal (not shown in FIG. 1), the row decoder 108 performs a refresh operation on the word line(s) associated with the refresh address RXADD. The refresh control circuit 116 performs refresh operations based on one or more refresh signals. The refresh signals REF may be generated based on refresh commands such as partial or all bank refresh commands. The memory 100 may also receive a refresh management (RFM) commands and generate an RFM signal. In some modes, a refresh signal may be internally generated by the memory device 100 as part of a self-refresh mode. Response to the refresh signal, the refresh control circuit 116 performs one or more refresh operations of one or more different types.

As part of normal or CBR refresh operations, the refresh control circuit 116 generates the refresh address RXADD based on sequence logic. For example, each refresh address RXADD may be based on a previous refresh address such as RXADD (i)=RXADD (i-1)+1. The sequence logic may include an address counter which counts through the row addresses of the bank. In some embodiments, one or more bits of the refresh address RXADD may be masked compared to a full row address XADD. In this way, each of the word lines which shares the non-masked portion in common may be refreshed at one time.

The refresh control circuit 116 also performs targeted refresh operations. When a PRAC value crosses a threshold, the address associated with that PRAC value is added to an aggressor queue. When a targeted refresh is performed, the refresh control circuit 116 generates a refresh address RXADD based on the address in the queue. The targeted refresh addresses reflect the addresses of word lines which have a physical relationship with the aggressor word line, such as the word lines adjacent to the aggressor and/or the word lines adjacent to those word lines. The refresh control circuit 116 may perform a set of targeted refresh operations based on a single address in the queue. The final targeted refresh operation of the set is a reset targeted refresh operation. For example if HitXADD is the aggressor address stored in the queue, and the adjacent word lines are being refreshed, then the set includes 3 targeted refresh operations, RXADD=HitXADD +1, HitXADD−1, and the reset operation on HitXADD. If the word lines adjacent to the adjacent word lines are being refreshed, then the set includes 5 targeted refresh operations RXADD=HitXADD+1, HitXADD−1, HitXADD+2, HitXADD−2, and the reset operation on HitXADD.

When an address HitXADD is added the aggressor queue the current value of the PRAC value associated with that address is stored along with it. When the refresh control circuit 116 performs a reset targeted refresh operation on HitXADD, a gap logic circuit 117 of the refresh control circuit 116 reads a current version of the PRAC count and compares it to the stored version. If there is not a difference, the PRAC value is reset to an initial level, such as zero. If there is a difference, then the PRAC value is set to the difference. In this way, activations which happen in the gap between identifying the

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

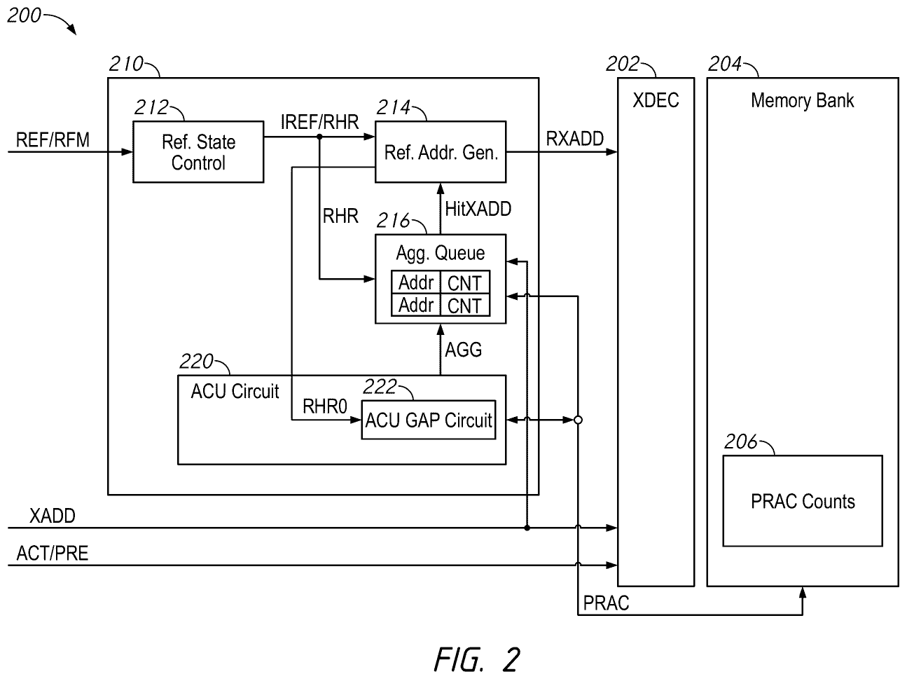

FIG. 2 is a block diagram of bank logic according to some embodiments of the present disclosure. The bank logic 200 may, in some embodiments, implement a portion of a memory device, such as the memory device 100 of FIG. 1. The bank logic 200 includes a refresh control circuit 210 (e.g., 116 of FIG. 1) a row decoder 202 (e.g., 108 of FIG. 1) and a memory bank 204 (e.g., 118 of FIG. 1). The components shown as part of the bank logic 200 may generally be repeated on a back by bank basis. For the sake of clarity, certain signals and components have been omitted from the view of the bank logic 200 in FIG. 2. For example, circuit such as a column decoder (e.g., 110 of FIG. 1) not shown in FIG. 2 may also be part of the bank logic.

As part of a refresh operation the refresh control circuit 210 provides a refresh address RXADD to the row decoder 202. The row decoder 202 activates and refreshes one or more word lines in the bank 204 associated with the row address RXADD. The refresh control circuit 210 receives signals such as REF or RFM and performs one or more refresh operations. The refresh control circuit 210 includes a refresh state control circuit 212, a refresh address generator circuit 214, an aggressor queue circuit 216, and an ACU circuit 220.

The refresh control circuit 210 includes a refresh state control circuit 212 which determines what type(s) and how many refresh operations to perform responsive to REF or RFM. The refresh control circuit 210 provides internal signals such as an internal normal refresh signal IREF and an internal targeted refresh signal RHR. The signals IREF and RHR indicate the number and type of refresh operation to perform. For example, when IREF alone is active, it may indicate a normal refresh operation, but when both IREF and RHR are active, it may indicate a targeted refresh operation. Other patterns of signals may be used in other example embodiments, for example the activation of IREF and RHR may be mutually exclusive.

The refresh state control circuit 212 performs different numbers and different types of refresh operation based on different refresh commands such as REF or RFM, internal logic, or combinations thereof. For example, responsive to the refresh signal REF, generated in response to an all-bank, per-bank, or sub-bank refresh operation, the refresh state control circuit 212 may perform a first number of refresh operations. The first number may be a mix of normal refresh operations and targeted refresh operations. Responsive to the refresh management signal RFM, generated responsive to an RFM command, the refresh state control circuit 212 may perform a second number of refresh operations, all of which are targeted refresh operations. In an example implementation, responsive to REF, the refresh state control circuit 212 may perform two refresh operations, one normal refresh (e.g., IREF is active) and one targeted refresh operation (e.g., both IREF and RHR are active). Responsive to the RFM command, the refresh state control circuit 212 may perform five targeted refresh operations (e.g., both IREF and RHR are active). Other numbers and mixes of refresh operations types may be used in other example embodiments.

The refresh address generator 214 generates the refresh address RXADD responsive to the internal refresh signals IREF, RHR or combinations thereof. If the internal signals indicate a normal refresh operation, then the refresh address generator circuit 214 generates RXADD based on sequence logic. For example, the refresh address generator circuit 214 may include a refresh address counter. When a normal refresh operation is performed, the refresh address counter updates (e.g., increments) to generate a new value of RXADD. If the internal signals indicate a targeted refresh operation, then the refresh address generator circuit 214 generates RXADD based on an aggressor address HitXADD stored in the aggressor queue 216.

The aggressor queue 216 includes one or more storage elements organized into a register which stores addresses and associated information. For example, content addressable memory (CAM) circuits may be used as part of the register. The queue 216 may operate as a FIFO queue in some embodiments. The register may be organized into slots, each of which is organized into one or more fields which store related pieces of information. For example a slot may have a field for the address and a field for the count value related to that address.

The refresh control circuit 210 may perform a sequence of refresh operations based on a single aggressor address. The sequence includes targeted refresh operations on addresses associated with word lines which have a spatial relationship with the word line associated with HitXADD and a reset targeted refresh operation on HitXADD. The different targeted refresh operations in the set may be performed responsive to different refresh commands. For example, a first portion of the targeted refresh operations on a given aggressor may be performed responsive to a first refresh command, while a second portion of the targeted refresh operations on that aggressor may be performed responsive to a second refresh command. The number of operations performed as part of the sequence may vary. An example sequence may include three targeted refresh operations on HitXADD-1, HitXADD+1 and a reset of HitXADD. Another sequence includes HitXADD−1, HitXADD+1, HitXADD−2, HitXADD+2, and the reset of HitXADD. The aggressor queue 216 may include a flag for each stored address which indicates how long the sequence should be for that address. For example, an R2 flag or field in the queue 216 indicates if the +/−2 refreshes should be performed or not.

Each time the refresh address generator performs a targeted refresh operation, it checks to see if there is a current address. If there is not, it selects a next address in the queue 216 and performs a first targeted refresh in the set. When a new address is selected, the count value associated with that address is locked. If there is a current address, the refresh address generator 214 performs a next targeted refresh in the set. If the current targeted refresh operation is the final targeted refresh in the set for that address, the refresh address generator provides HitXADD as RXADD and performs a reset targeted refresh operation by sending a signal RHRO to the ACU circuit 220.

The ACU circuit 220 performs ACU operations when a word line is accessed. When the row decoder 202 activates a word line in the bank 204, the PRAC value associated with that word line is read out from the counter memory cells 206 to the ACU circuit. The ACU circuit 220 performs an ACU operation by updating the count value, for example by incrementing the count. If the count crosses a mitigation threshold, then the ACU circuit 220 provides an aggressor detected signal to the queue 216. If that address was not already in the queue 216, then the current row address XADD and count value PRAC are stored in the queue 216. If the address was already in the queue 216, and that queue slot is not locked, then the count value stored in the queue 216 is updated. If the address is in the queue 216 and the queue slot is locked, then the count is not updated. Whether the count has crossed the threshold or not, the updated count value is written back to the counter memory cells 206.

The ACU circuit 220 includes an ACU gap logic circuit 222. When the ACU circuit 220 receives the reset targeted refresh signal RHRO, the ACU gap logic circuit 222 reads the current value of the PRAC count associated with the current aggressor address HitXADD and compares that value to the value stored in the register 216. Since the value in the register was locked, the value in the register will represent the access count at the time the first targeted refresh operation was performed based on that aggressor address. The value read from the counter memory cells 206 will be updated to reflect any access operations which occurred in the gap of time between the first targeted refresh operation of the set and the reset targeted refresh operation. The ACU gap logic circuit 222 finds the difference between the two values, for example by subtracting the stored PRAC value from the queue 216 from the freshly read PRAC value from the counter memory cells 206, and writes that difference back to the counter memory cells 206 as part of the reset targeted refresh operation. In this way, the PRAC count in the counter memory cells will be set to the gap value, representing any changes to the access count which occurred in the gap between the first and last targeted refresh operations of the set of targeted refresh operations performed on that address.

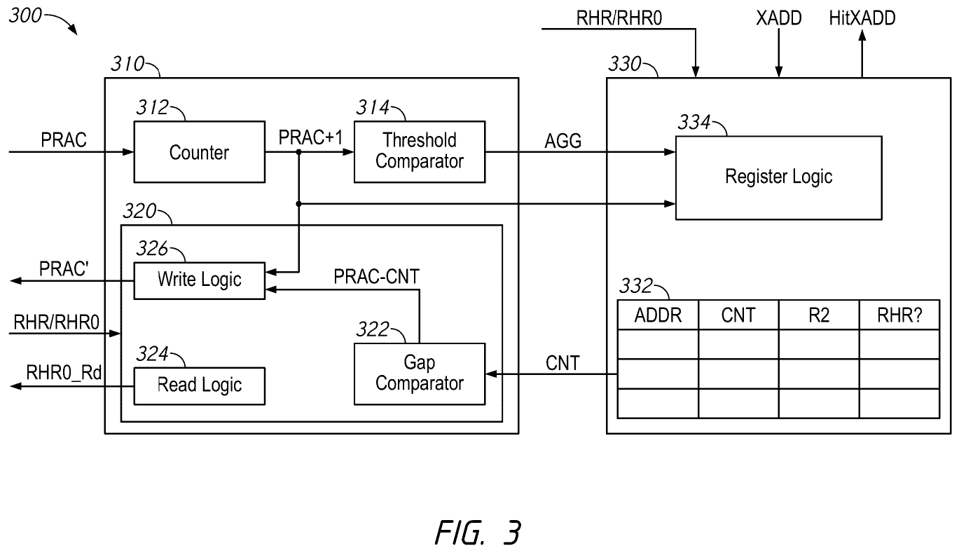

FIG. 3 is a block diagram of gap logic circuits according to some embodiments of the present disclosure. The gap logic circuits 300 may, in some embodiments, implement a portion of a refresh control circuit such as 116 of FIGS. 1 and/or 210 of FIG. 2. The gap logic circuits 300 show an ACU circuit 310 (e.g., 220 of FIG. 2) which includes an ACU gap circuit 320 (e.g., 117 of FIGS. 1 and/or 222 of FIG. 2). The gap logic circuits 300 also show an aggressor queue 330 (e.g., 216 of FIG. 2) which includes an aggressor register 332. The gap logic circuits 300 show components and signals useful to determining gap updates. Certain other signals and components have been omitted from the view of FIG. 3.

The ACU circuit 310 receives a PRAC value when a word line is accessed. For example, the PRAC value may be received responsive to a row activation command or responsive to a pre-charge command in some embodiments. The ACU circuit 310 includes a counter circuit 312 which updates the PRAC value as part of the ACU operation. For example, the counter circuit 312 may increment the PRAC value. The updated count value provided by the counter circuit 312 is represented as PRAC+1, in FIG. 3, however other ways of updating the count besides incrementing may also be used.

The ACU circuit 310 also includes a threshold comparator circuit 314 which compares the updated count value PRAC+1 to one or more threshold. For example, the updated count value PRAC+1 may be compared to a mitigation threshold MT and to an alert threshold AT. The alert threshold AT may generally be a higher value than the mitigation threshold MT. If the updated count value PRAC+1 has crossed the mitigation threshold MT, for example by being greater than or equal to mitigation threshold, then the threshold comparator circuit 314 provides an aggressor signal AGG. If the updated count value PRAC+1 has crossed the alert threshold, then the ACU circuit 310 may send an alert signal. For example, the alert signal may be provided to a controller of the memory and responsive to that signal the controller may initiate a pause to allow more targeted refresh operations to be performed. As explained in more detail herein, if a reset targeted refresh operation is not being performed, for example when a reset targeted refresh signal RHRO is inactive, then a write logic circuit 326 of the ACU gap circuit 320 writes the updated count value PRAC+1 back to the counter memory cells as write value PRAC′.

The aggressor queue 330 includes a register 332 and register logic 334 which manages the contents of the register 332. The register 332 includes storage elements, such as latch circuits, which store binary information. The storage elements are organized into one or more slots, each of which includes one or more fields. Each slot can store a row address as well as associated information in the other fields. In the example implementation of FIG. 3, the register 332 includes four fields per slot, an address field, a count field CNT, an R2 field, and an RHR execution field. The address field stores an address identified as an aggressor and the count field stores the PRAC value associated with that address. The R2 field indicates if +/−2 refreshes will be performed on the address. The RHR execution field indicates if the field is currently being used for targeted refresh operations.

When the register logic 334 receives the aggressor signal, it compares the row address XADD to the stored addresses in the register 332. If there is a match, and that slot has the RHR execution field at an inactive level, then the updated count value PRAC+1 is written to the slot that stores that address as the new count CNT. If there is not a match, then the address XADD and the count PRAC+1 are written to the register 332. If there is an open slot, the address and count PRAC+1 are written there. If there is not an open slot, then the register logic 334 may use various logic to determine what to do. For example, a newest entry in the register 332 may be overwritten in some embodiments, an entry with the lowest count value may be overwritten in some embodiments, or other criteria may be used.

When the aggressor queue 330 receives the RHR signal, indicating that a targeted refresh should be performed, the register logic 334 checks if any of the slots in the register 332 have an active RHR execution field. If so, then the address in that slot is provided as the aggressor address HitXADD. If there is not, then the register logic 334 selects one of the slots and activates its RHR execution field. For example, the RHR execution field may be a single bit which is at a high logical level when active and at a low logical level when inactive. The register logic 334 then provides the address in that slot. While the RHR execution field is active, the count field for that slot is locked. For example, the register logic 334 will not update the count value CNT to PRAC+1 when that field has an active RHR execution field. In this way, the count value is locked at the value it was when a set of targeted refresh operations began being performed based on that address.

The register logic 334 may sometimes set the field R2 to an active level. Similar to the RHR execution field, the field R2 may be a single bit, which is active at a logical high and inactive at a logical low in some embodiments. The field R2 indicates how many refresh operations will be performed as part of a refresh set. For example, if R2 is inactive then three targeted refresh operations will be performed on the address in that slot (−1, +1, and RHRO). If R2 is active, then five targeted refresh operations will be performed on the address in that slot (−1, +1, −2, +2, RHRO). Accordingly, whether R2 is active or not determines when the signal RHRO is provided. The register logic 334 may set R2 based on various logic. For example, every Nth time a new aggressor address is selected, then R2 may be set.

The ACU gap logic circuit 320 sets the value of PRAC′ which is written back to the memory cells during a reset targeted refresh operation. The ACU gap logic circuit 320 includes a gap comparator circuit 322, a read logic circuit 324, and a write logic circuit 326. Responsive to a reset targeted refresh operation, for example when the signal RHRO is active, the read logic circuit 324 performs a read operation on the PRAC value of the aggressor word line HitXADD. For example, the read logic circuit 324 provides a signal RHRO_Rd and the queue 330 provides the address HitXADD from the slot where the RHR execution field is active. Responsive to this the value PRAC is read out from the counter memory cells associated with HitXADD.

The gap comparator circuit 322 takes a difference between the current PRAC value read from the array and the value CNT which was locked in the register 332 when targeted refresh operations begin. The gap comparator circuit 322 generates a gap value PRAC-CNT, which represents how many activations have occurred since the targeted refresh operations began. Responsive to the reset targeted refresh operation, the write logic 326 provides the gap value PRAC-CNT as the write value PRAC′. If it is not a reset targeted refresh operation provides the value RPAC+1 as the write value PRAC′. The write value PRAC′ is written to the counter memory cells along the word line XADD during a normal access operation or to HitXADD during a reset targeted refresh operation.

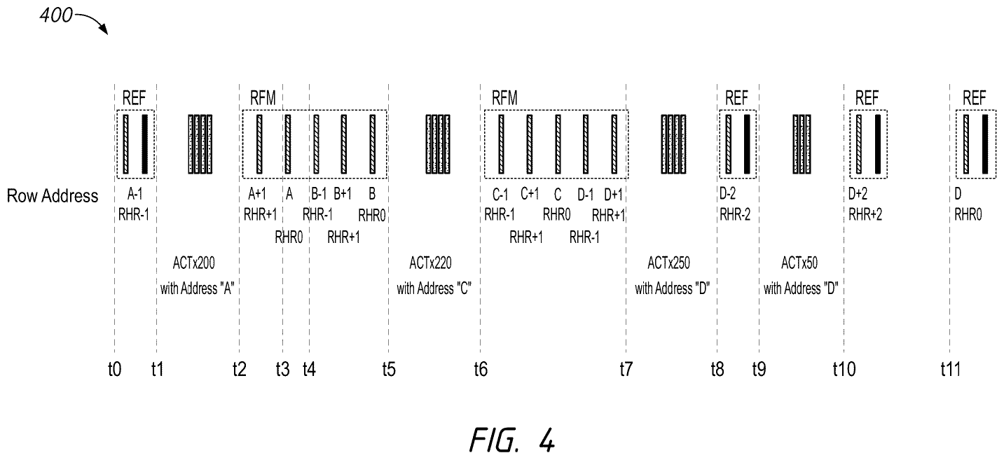

FIG. 4 is a chart of an example sequence of operations according to some embodiments of the present disclosure. The chart 400 may represent operations a memory device, such as the memory device 100 of FIG. 1. The chart shows operations where refresh operations are performed, such as by a refresh control circuit (e.g., 116 of FIG. 1, 210 of FIGS. 2, and/or 300 of FIG. 3).

The chart shows operations represented by vertical lines, extending in time from time t0 to time t11. The axis representing time is not drawn to any particular scale and is only meant to show the relative placement of different operations in time. The operations include targeted refresh operations, normal refresh operations, and access operations. Boxes are shown to indicate the sequence of refresh operations performed responsive to a refresh signals such as REF or RFM generated responsive to a refresh command. Row addresses are represented by letters below the operation to indicate which address the operations are performed on.

At an initial time to, the memory receives a refresh command and generates the refresh signal REF and performs two refresh operations, a targeted refresh operation and then a normal refresh operation. At the time to, no address is currently being used for targeted refresh operations, so a new address ‘A’ is selected from the targeted refresh queue (e.g., 216 of FIGS. 2 and/or 330 of FIG. 3). For example, at the time to there may be no slots with an active RHR execution field, and so address A is selected by the register logic (e.g., 334 of FIG. 3) its RHR execution field is activated, and address A is provided as the aggressor address. The refresh address generator provides an address A-1 as the refresh address and a targeted refresh is performed on that address.

At a time t1, the two refresh operations have been performed, and so the memory is available for access operations until a time t2 when a next refresh command, in this case RFM is received. The time between t1 and t2 represents a gap, where access operations could be performed on address A. In the example of FIG. 4, 200 access operations are performed on address A. An ACU circuit (e.g., 220 of FIGS. 2 and/or 310 of FIG. 3) continues to update the PRAC count associated with address A. However, because the RHR execution field is active, the count value in the aggressor register will not change. Accordingly, the PRAC count in the array will have a value which is 200 greater than the value stored in the register. At the time t2, an RFM command is received.

Responsive to an RFM command, five targeted refresh operations are performed. The first targeted refresh is on the address A+1, since the slot containing address A has an active RHR execution field. The next targeted refresh operation at time t3 is a reset targeted refresh operation RHRO on address A. At the time t3, the gap logic circuit (e.g., 117 of FIG. 1, 222 of FIGS. 2, and/or 320 of FIG. 3) takes the difference between the count value stored in the array and the count value in the register. In this case, that difference is 200, since 200 accesses to row A were performed in the gap between the refresh set starting for address A at time to and the reset targeted refresh operation for address A at time t3. That difference, in this case 200, is written back to the array as the new PRAC value for address A at time t3. Since a reset targeted refresh operation was performed on row A, it is removed from the register and the fields of that register reset.

At a time t4, the third of the five targeted refresh operations in the sequence triggered by the RFM command at time t2, the register selects a next address, in this case B. Since there are three remaining targeted refresh operations in the sequence, B will have all three operations, B−1, B+1, and B RHRO, performed with not possibility of a gap. Since there were no accesses to row B between the time t4 and the time t5 when refresh operations end, the PRAC value for row B will be reset to 0, since the locked and read PRAC values will be the same value.

At the time t5, access operations resume and are performed on row C. At the time t6, another RFM is received. Similar to the time t4, a new address is needed, so at t6, the register provides address C as the aggressor. Three targeted refresh operations are performed, and so row C's PRAC value is set to 0, since no accesses occur between times t6 and the reset targeted refresh on row C. The next aggressor address is row D, however, unlike rows A, B, and C, row D has its R2 flag set. Since there are two remaining targeted refresh operations, D−1 and D+1 are both refreshed. A the time t7, access operations resume for a time before a refresh command is received at time t8. Between the times t7 and t8, 250 accesses are performed on row D. At the time t8, a refresh command REF is received and so a single targeted refresh operation and a normal refresh operation are performed. The targeted refresh operation is sued to refresh D−2. At a time t9, access operations begin again, and 50 more accesses are performed on D before a next refresh command at time t10. The targeted refresh command at time t10 is used to refresh D+2. There is another span of time with access commands before the next refresh is received at time t11, however no accesses are performed on row D. At t11 a refresh command is received and the reset targeted refresh is performed on row D. The PRAC value for row D is set to a value of 300, since 300 total accesses were performed in the gap between times t7 and t11.

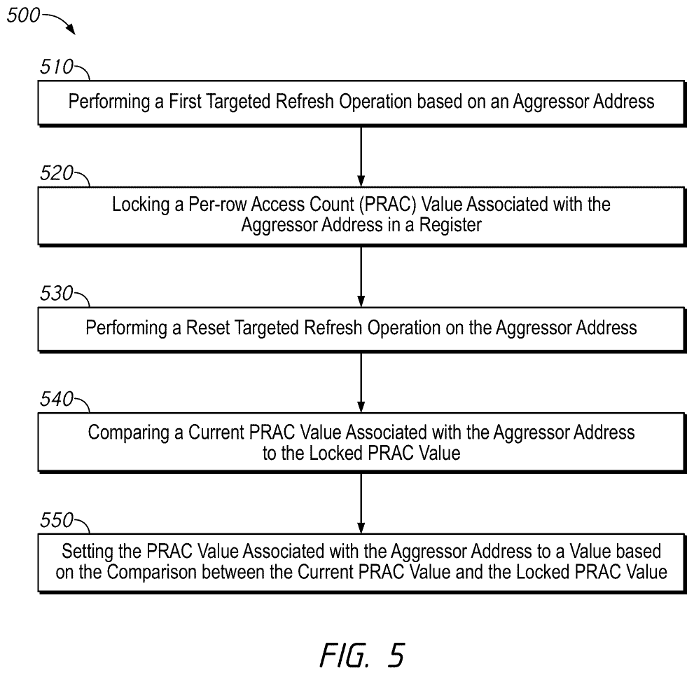

FIG. 5 is a flow chart of a method of adjusting PRAC values based on activations during a targeted refresh gap according to some embodiments of the present disclosure. The method 500 may, in some embodiments, be performed by one or more of the apparatuses or systems described herein. For example, the method 500 may be performed by the memory device 100 of FIG. 1, the bank logic 200 of FIG. 2, the gap logic circuits 300 of FIG. 3 or combinations thereof.

The method 500 may begin with box 510, which describes performing a first targeted refresh operation based on an aggressor address. The method 500 may include receiving a refresh signal, such as REF or RFM, at a refresh control circuit such as 116 of FIG. 1, 210 of FIGS. 2, and/or 300 of FIG. 3. Box 510 may include checking an aggressor queue (e.g., 216 of FIGS. 2, and/or 330 of FIG. 3) to see if there is an aggressor address already being refreshed. For example, the method may include checking the RHR execution fields in the register (e.g., 332 of FIG. 3) to see if there is a slot with an active RHR execution field. If there is not a slot with an active RHR execution field, then box 510 is performed, and a first targeted refresh operation is performed based on the aggressor address. For example, a refresh address generator circuit (e.g., 214 of FIG. 2) generates a refresh address based on the aggressor address. If a slot has an active RHR execution field, then targeted refresh operations will continue to be performed based on the address in that slot.

Box 510 is generally followed by box 520, which describes locking a PRAC value associated with the aggressor address in a register responsive to performing the first targeted refresh operation. For example, the method 500 may include updating a PRAC value in a memory array when the aggressor address is accessed. The method 500 may include updating the PRAC value in the register when the PRAC value is updated if the PRAC value in the register is unlocked. The method 500 may include updating the PRAC value in the array but not the PRAC value in the register if the PRAC value in the register is locked. The method 500 may include locking the register by setting an RHR activation field associated with the aggressor address to an active state.

Box 520 may generally be followed by box 530 which describes performing a reset targeted refresh operation on the aggressor address. The method 500 may include performing a set of targeted refresh operations based on the aggressor address, where the reset targeted refresh operation is a final targeted refresh operation in the set. The method may include determining a number of targeted refresh operations in the set based on a state of an R2 filed in the register.

Box 530 may generally be followed by box 540, which describes comparing a current PRAC value associated with the aggressor address to the locked PRAC value in the register as part of performing the reset targeted refresh operation. The method 500 may include reading the current PRAC value from the memory array. For example, the method 500 may include providing a reset targeted refresh read command (e.g., RHRO_Rd) as well as the aggressor address. The comparison may include subtracting the locked value from the current value to generate a gap value, for example with a comparator circuit (e.g., 322 of FIG. 3).

Box 540 may generally be followed by box 550, which describes setting the PRAC value associated with the aggressor address to a value based on the comparison between the current PRAC value and the locked PRAC value. For example, the reset targeted refresh operation may include writing the gap value to the memory array as the new PRAC value. Responsive to performing the reset targeted refresh operation, the method 500 may include removing the aggressor address and count from the register.

In some embodiments, the steps of boxes 510 and 520 may be performed responsive to a first refresh command such as a first REF or RFM signal, while the steps of boxes 530 to 550 may be performed responsive to a second refresh command, such as a second REF or RFM signal. In some embodiments, one or more access operations may be performed boxes 520 and 530. In some embodiments, additional targeted refresh operations may be performed on the aggressor address between boxes 520 and 530.

The method may include updating the PRAC value when the aggressor address is accessed. For example, the method may include incrementing the PRAC value. The method may include comparing the updated PRAC value to a mitigation threshold (e.g., with a threshold comparator such as 314 of FIG. 3). If the updated PRAC has crossed the mitigation threshold, the method 500 may include adding the aggressor address to the aggressor queue.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array comprising a plurality of word lines, each associated with a per-row access count (PRAC) value;
a refresh control circuit configured to identify a selected one of the plurality of word lines as an aggressor word line based on the associated PRAC value,
wherein the refresh control circuit is configured to perform a set of targeted refresh operations based on the aggressor word line, and
wherein the refresh control circuit is configured to set the associated PRAC value based on a number of access operations performed on the selected one of the word lines in the time between a first of the set of targeted refresh operations and a last of the set of targeted refresh operations as part of the last of the set of targeted refresh operations.

2. The apparatus of claim 1, wherein the refresh control circuit comprises a register configured to store an aggressor address associated with the aggressor word line and the PRAC value associated with the aggressor word line at the time of the first of the targeted refresh operations.

3. The apparatus of claim 2, wherein the refresh control circuit comprises a gap logic circuit configured read a current value of the PRAC value associated with the aggressor word line and write a difference between the current value and the stored value in the register as a new PRAC value to the word line responsive to the last of the set of targeted refresh operations.

4. The apparatus of claim 1, wherein the set of targeted refresh operations includes refresh operations on word lines near the aggressor word line and wherein the last of the set of targeted refresh operations is a reset targeted refresh operation on the aggressor word line.

5. The apparatus of claim 1, wherein the refresh control circuit is configured to perform a first of the set of targeted refresh operations responsive to a first refresh command and configured to perform the last of the set of targeted refresh operations responsive to a second refresh command.

6. The apparatus of claim 5, further comprising a row decoder configured to perform one or more access operations on the selected one of the word lines responsive to one or more access commands received between the first refresh command and the second refresh command.

7. A method comprising:
performing a first targeted refresh operation based on an aggressor address;
locking a per-row access count (PRAC) value associated with the aggressor address in a register responsive to performing the first targeted refresh operation;
performing a reset targeted refresh operation on the aggressor address;
comparing a current PRAC value associated with the aggressor address to the locked PRAC value; and
setting the PRAC value associated with the aggressor address to a value based on the comparison between the current PRAC value and the locked PRAC value.

8. The method of claim 7, further comprising:
subtracting the locked PRAC value from the current PRAC value to generate a gap value; and
writing the gap value to a memory array as the new PRAC value as part of the reset targeted refresh operation.

9. The method of claim 7, further comprising reading the current PRAC value from a memory array as part of performing the reset targeted refresh operation.

10. The method of claim 7, further comprising setting a targeted refresh execution field to an active level responsive to performing the first targeted refresh operation.

11. The method of claim 10, further comprising:
updating the PRAC value responsive to an access on the aggressor address;
writing the updated PRAC value to a memory array;
storing the updated PRAC value in the register as the stored PRAC value if the RHR execution field is inactive; and
leaving the stored PRAC value if the RHR execution field is active.

12. The method of claim 10, further comprising:
receiving a targeted refresh signal;
checking the register to determine if there is a slot with an active RHR execution field; and
selecting the aggressor address and performing the first targeted refresh operation if there is not a slot with an active RHR execution tag.

13. The method of claim 7, further comprising:
updating the PRAC value responsive to an access on the aggressor address; and
Storing the aggressor address and the PRAC value in the register responsive to the PRAC value crossing a threshold.

14. The method of claim 7, further comprising:
performing the first targeted refresh operation responsive to a first refresh command; and
performing the reset targeted refresh operation responsive to a second refresh command.

15. The method of claim 14, further comprising receiving one or more access commands between the first refresh command the second refresh command.

16. An apparatus comprising:
a memory array configured to store a plurality of count values, each associated with one of a plurality of addresses;
an aggressor queue comprising a plurality of slots, each slot configured to store an address, an associated count value, and an execution field; and
an access count update logic circuit configured to perform a reset targeted refresh operation based on the address in one of the plurality of slots with an active execution field by writing a difference between a current count value read from the memory array and the associated count value in the aggressor queue to the memory array.

17. The apparatus of claim 16, wherein the reset targeted refresh operation is a last of a set of targeted refresh operations performed based on the address in the one of the plurality of slots with an active execution field.

18. The apparatus of claim 16, wherein the access count update logic circuit is configured to read the current count value from the memory array responsive to the reset targeted refresh operation.

19. The apparatus of claim 16, wherein the access count update logic circuit is configured to update a selected one of the count values in the memory array responsive to an access on an accessed address, and configured to store the updated count value in the aggressor queue as the count value if the accessed address matches the address and the execution field is inactive.

20. The apparatus of claim 19, wherein the access count update logic circuit is configured to add the accessed address to the aggressor queue if the updated count value crosses a mitigation threshold and the accessed address is not stored in the aggressor queue.
